(19) United States
(12) Patent Application Publication
(10) Pub. No.: US 2015/0079786 A1
(43) Pub. Date: Mar. 19, 2015

(54) METHOD AND SOLUTION FOR CLEANING METAL RESIDUE

(71) Applicant: Lam Research Corporation, Fremont, CA (US)

(72) Inventors: Samantha S.H. Tan, Fremont, CA (US); Alexander Kabansky, Santa Clara, CA (US); Joydeep Guha, Fremont, CA (US)

(21) Appl. No.: 14/029,391

(22) Filed: Sep. 17, 2013

(51) Int. Cl. H01L 21/306; C09K 13/00; C09K 13/06

(52) U.S. Cl. CPC H01L 21/30604; C09K 13/06; C09K 13/00
USPC 438/669; 252/79.1; 252/79.4

(57) ABSTRACT

A solution for processing devices is provided, comprising an activator comprising at least one of pyridine, pyrole, pyrrolidine, pyrimidine, N,N-dimethylformamide, tetraethylamine chloride, 4 pyridinethiol, or other organic compounds with a single N with a lone pair electron activator and an etchant comprising at least one of thionly chloride, Cl₂, Br₂, I₂, SOF₂, SOF₄, SO₂Cl₂, SOBr₂, S₂O₆F₂, HSO₃F, or C₂Cl₄O₂.

### BACKGROUND OF THE INVENTION

The present invention relates to methods and solutions for cleaning. More specifically, the present invention relates to methods and solutions for cleaning metal residues.

During semiconductor wafer processing, the processing of metal containing layer may cause metal residue. It is desirable to remove such metal residue.

### SUMMARY OF THE INVENTION

To achieve the foregoing and in accordance with the purpose of the present invention, a solution for processing devices is provided, comprising an activator comprising at least one of pyridine, pyrrole, pyrrolidine, pyrimidine, N,N-dimethylformamide, tetraethylamine chloride, 4 pyridinethiol, or other organic compounds with a single N with a lone pair electron activator and an etchant comprising at least one of thionyl chloride (SOCl2), Cl₂, Br₂, I₂, SOF₂, SOF₄, SO₂Cl₂, SOBr₂, or C₂Cl₄O₂.

In another manifestation of the invention, a method for forming semiconductor devices on a substrate with at least one metal layer is provided. The at least one metal layer is exposed to a solution. The solution comprises an activator comprising at least one of pyridine, pyrole, pyrrolidine, pyrimidine, N,N-dimethylformamide, tetraethylamine chloride, 4 pyridinethiol, or other organic compounds with a single N lone pair electron activator and an etchant comprising at least one of thionyl chloride (SOCl2), Cl₂, Br₂, I₂, SOF₂, SOF₄, SO₂Cl₂, SOBr₂, or C₂Cl₄O₂.

In another manifestation of the invention, a solution for processing semiconductor devices is provided, comprising a nonaqueous solvent and an acid precursor.

In another manifestation of the invention, a method for forming semiconductor devices on a substrate with at least one metal layer is provided. The at least one metal layer is exposed to a solution, comprising a nonaqueous solvent and an acid precursor.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIGS. 2A-B are schematic views of a stack processed according to an embodiment of the invention.

FIG. 3 is a high level flow chart of another embodiment of the invention.

FIGS. 4A-B are schematic views of a stack processed according to another embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

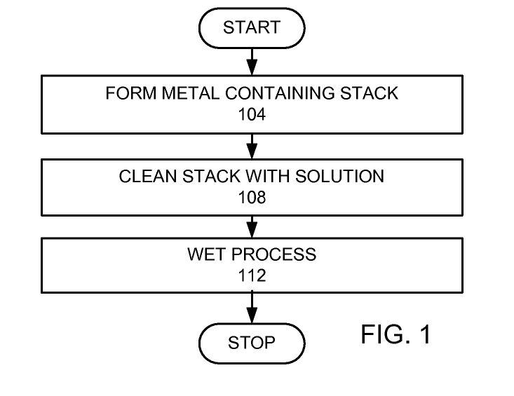

To facilitate understanding, FIG. 1 is a high level flow chart of a process used in an embodiment. A metal containing stack is formed (step 104). The stack is cleaned with a solution (step 108). A wetting process is performed on the stack after exposure to the solution (step 112).

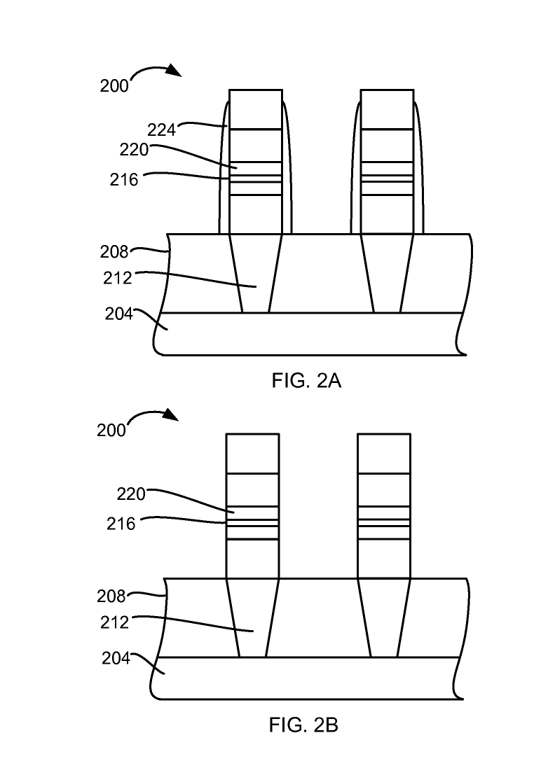

In an embodiment, a metal containing stack is formed (step 104). FIG. 2A is a cross-sectional view of a stack 200 with a substrate 204 over which one or more intermediate layers 208 has been formed. The one or more intermediate layers 208 may have conductors 212, such as contacts, trenches or vias. Stacks 216 with one or more layers are formed over the one or more intermediate layers 208. A metal containing layer 220 forms at least one layer of the stacks 216. In an example of this embodiment, the metal containing layer may be formed from one or more layers of titanium nitride (TiN), tantalum (Ta), and ruthenium, (Ru). In the formation of the stacks 216, such as during a dry etching process, sidewalls of residue 224 are formed. Since one or more of the layers contains metal, the sidewalls of residue 224 contain metal, which may cause shorting between layers of the stacks 216. In some embodiments the residue comprises a transition metal, an alkali metal and a noble metal.

The stack 200 is cleaned using a solution (step 108). In this embodiment, the solution is a nonaqueous solution of pyridine and SOCl₂. The ratio of pyridine and SOCL₂ is 1:1 at room temperature. The stacks 216 are exposed to the solution for 30 seconds.

FIG. 2B is a cross-sectional view of a stack 200 after the solution has been removed. The sidewalls of residues are removed with minimal etching of the layers of the stacks 216.

In this embodiment, a subsequent wet process is provided (step 112). The wet process is used to rinse off the cleaning solution and to stop the reaction.

The combination of an activator and an etchant improves the etching ability of the solution. However, a diluent is also needed to provide selectivity. The ratio of the activator and etchant and the diluent may be used to tune selectivity and activity. It has found in embodiments that pyridine may act as both an activator and buffer.

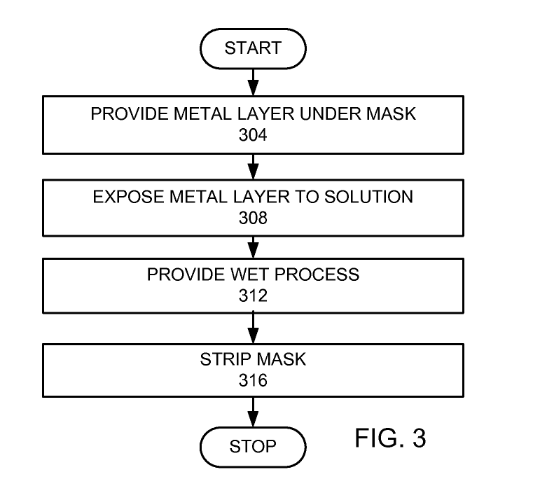

FIG. 3 is a high level flow chart of another embodiment of the invention. A metal layer is provided under a mask (step 304). The metal layer is exposed to a solution (step 308) to etch the metal layers. The metal layer is exposed to a wet process (step 312) to rinse of the chemical solution. The mask is stripped (step 316).

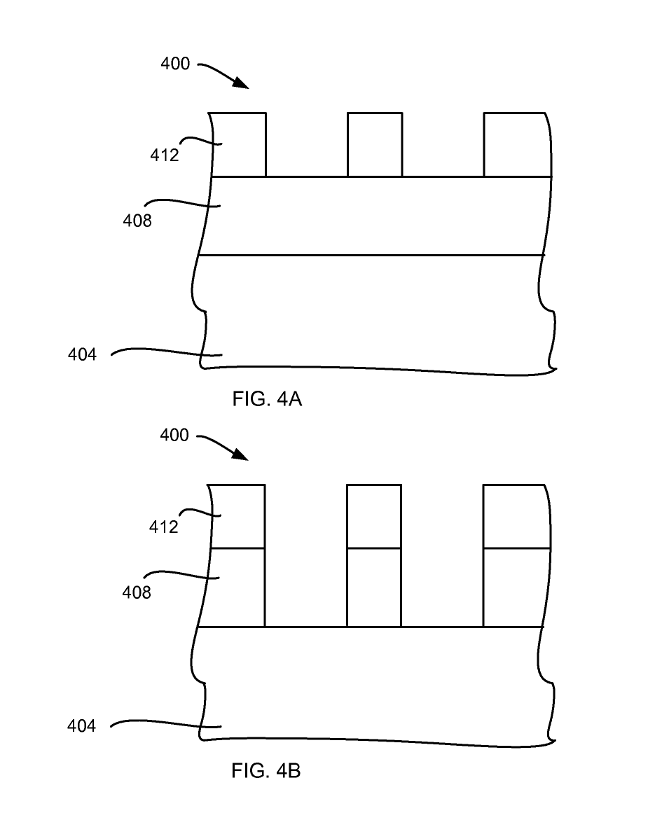

In an example of this embodiment of the invention, the same metal stack is provided below a photoresist mask (step 304). FIG. 4A is a schematic cross-sectional view of a stack 400 comprising a substrate 404 under a metal layer 408, which is under a patterned mask 412. The metal layer 408 is exposed to the solution (step 308). In this embodiment, the solution is in vapor form. In this example, the solution is SOCl₂ with pyridine. The solution etches the metal layer 408. FIG. 4B is a schematic cross-sectional view of the stack after the metal layer 408 is etched by the solution. The metal layer 408 is then subjected to a wet process (step 312). In this example the wet process is uses an inert nonaqueous solvent to remove residue and vapor, since the solvent in inert and nonaqueous, the solvent does not corrode or damage the stack. The patterned mask 412 is stripped (step 316). The stripping may be accomplished using an ashing step or a wet strip.

In some embodiments, the nonaqueous solution comprises an activator comprising at least one of pyridine, pyrole, pyrrolidine, pyrimidine, N,N-dimethylformamide (DMF), tetraethylamine chloride, 4 pyridinethiol, or other organic compounds with a single N lone pair activator and an etchant comprising at least one of thionyl chloride, Cl₂, Br₂, I₂, SOF₂, SOF₄, SO₂Cl₂, SOBr₂, or C₂Cl₄O₂. Some embodiments of the invention further comprise a diluent. In an embodiment of the invention, the diluents comprise at least one of acetonitrile, dimethyl sulphoxide (DMSO), sulfolane, halogenated hydrocarbon solvents, or alcohols. In some embodiments, the solution is in liquid phase. In other embodiments, the solution is in vapor phase. In embodiments of the invention, the activator comprises at least one of pyrrole, pyrrolidine, pyrimidine, N,N-dimethylformamide, tetraethylamine chloride, or 4 pyridinethiol. In embodiments of the invention, the etchant comprises at least one of Cl₂, Br₂, I₂, SOF₂, SOF₄, SO₂Cl₂, SOBr₂, or C₂Cl₄O₂. Embodiments of the invention expose the stacks to the solution in a moisture free environment.

In some embodiments, the concentration of activator to the concentration of the etchant is from 0.1:99.9 to 99.9:0.1. More preferably, the concentration of activator to the concentration of etchant is from 10:90 to 90:10. More preferably, the concentration of activator to the concentration of etchant is from 30:70 to 70:30. Most preferably, the concentration of the etchant to the concentration of the activator is 1:1. Preferably, the concentration of diluent to remaining solution is from 0:100 to 70:30. More preferably, the concentration of diluent to remaining solution is from 20:80 to 50:50.

The combination of the active etchant with an activator provides a solution with improved etching abilities over the separate components. The ratio of the components provides control over the etching abilities. The addition of a diluent provides selectivity. Control of the diluent concentration provides a control over selectivity.

In another embodiment of the invention the solution comprises a nonaqueous solvent and an acid precursor. Preferably the acid precursor comprises at least one of organic acids such as HCO₂H, CH₃COOH, oxalic acid, malonic acid or other acid precursors such as HNO₃, HCl, H₃PO₄, SO₂, SO₃, Cl₂ or NO/NO₂. Preferably the nonaqueous solvent comprises at least one of ethylene glycol, acetonitrile, IPA, choline chloride, choline, urea, DMSO, DMF, or CCl₄. For example, the solution in one embodiment is acetic acid dissolved in ethylene glycol. By providing a nonaqueous solution metal residue may be removed or metal layers may be etched, while corrosion and other damage is reduced or minimized. It has been found that an aqueous solvent causes corrosion of the metal layers. In addition, an aqueous solvent may attack magnesium oxide dielectric barrier layers.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A solution for processing devices, comprising:
an activator comprising at least one of pyridine, pyrrole, pyrrolidine, pyrimidine, N,N-dimethylformamide, tetraethylamine chloride, 4 pyridinethiol, or other organic compounds with a single N with a lone pair electron activator; and
an etchant comprising at least one of thionyl chloride (SOCl₂), Cl₂, Br₂, I₂, SOF₂, SOF₄, SO₂Cl₂, SOBr₂, S₂O₆F₂, HSO₃F, or C₂Cl₄O₂.

2. The solution, as recited in claim 1, further comprising a diluent.

3. The solution, as recited in claim 2, wherein the diluent comprises at least one of acetonitrile, DMSO, sulfolane, halogenated hydrocarbon solvents, alcohols or other inert solvents.

4. The solution, as recited in claim 2, wherein the diluent is H₂O, acetone, and aldehyde free.

5. The solution, as recited in claim 2, wherein the solution is a liquid.

6. The solution, as recited in claim 1, wherein the solution is a vapor.

7. The solution, as recited in claim 1, wherein the activator comprising at least one of pyridine, pyrrole, pyrrolidine, pyrimidine, N,N-dimethylformamide, tetraethylamine chloride, or 4 pyridinethiol.

8. The solution, as recited in claim 1, wherein the etchant comprises at least one of Cl₂, Br₂, I₂, SOF₂, SOF₄, SOCl₂, SO₂Cl₂, SOBr₂, S₂O₆F₂, HSO₃F or C₂Cl₄O₂.

9. A method for forming semiconductor devices on a substrate with at least one metal layer, comprising exposing the at least one metal layer to a solution, comprising:
an activator comprising at least one of pyridine, pyrole, pyrrolidine, pyrimidine, N,N-dimethylformamide, tetraethylamine chloride, 4 pyridinethiol, or other organic compounds with a single N lone pair electron activator; and
an etchant comprising at least one of thionyl chloride, Cl₂, Br₂, I₂, SOF₂, SOF₄, SO₂Cl₂, SOBr₂, S₂O₆F₂, HSO₃F or C₂Cl₄O₂.

10. The method, as recited in claim 9, wherein the solution further comprises a diluent, comprising at least one of acetonitrile, DMSO, sulfolane, halogenated hydrocarbon solvents, or alcohol.

11. The method, as recited in claim 10, further comprising providing a moisture free environment.

12. The method, as recited in claim 11, wherein the diluent is H₂O, acetone, and aldehyde free.

13. The method, as recited in claim 12, wherein the solution is a liquid.

14. The method, as recited in claim 12, wherein the solution is a vapor.

15. A solution for processing semiconductor devices, comprising:
a nonaqueous solvent; and
an acid precursor.

16. The solution, as recited in claim 15, wherein the acid precursor comprises at least one of HCO₂H, CH₃COOH, oxalic acid, malonic acid, HNO₃, HCl, H₃PO₄, SO₂, SO₃, Cl₂ or NO/NO₂.

17. The solution, as recited in claim 16, wherein the nonaqueous solvent comprises at least one of ethylene glycol, acetonitrile, IPA, choline chloride, choline, urea, DMSO, DMF, or CCl₄.

18. A method for forming semiconductor devices on a substrate with at least one metal layer, comprising exposing the at least one metal layer to a solution, comprising:
a nonaqueous solvent; and
an acid precursor.

19. The method, as recited in claim 18, wherein the acid precursor comprises at least one of HCO₂H, CH₃COOH, oxalic acid, malonic acid, HNO₃, HCl, H₃PO₄, SO₂, SO₃, Cl₂ or NO/NO₂.

20. The method, as recited in claim 19, wherein the nonaqueous solvent comprises at least one of ethylene glycol, acetonitrile, IPA, choline chloride, choline, urea, DMSO, DMF, or CCl₄.
